(19) United States
(12) Patent Application Publication
(10) Pub. No.: US 2014/0117545 A1
(43) Pub. Date: May 1, 2014

(54) COPPER HILLOCK PREVENTION WITH HYDROGEN PLASMA TREATMENT IN A DEDICATED CHAMBER

(71) Applicants: Huang LIU, Singapore (SG); Xuesong Rao, Singapore (SG); Zheng Zou, Singapore (SG); Alex See, Singapore (SG); Lup San Leong, Singapore (SG); Liang Li, Singapore (SG); Chim Seng Seet, Singapore (SG)

(72) Inventors: Huang LIU, Singapore (SG); Xuesong Rao, Singapore (SG); Zheng Zou, Singapore (SG); Alex See, Singapore (SG); Lup San Leong, Singapore (SG); Liang Li, Singapore (SG); Chim Seng Seet, Singapore (SG)

(73) Assignee: GLOBALFOUNDRIES Singapore Pte. Ltd, Singapore (SG)

(21) Appl. No.: 13/661,882

(22) Filed: Oct. 26, 2012

(51) Int. Cl. H01L 21/768; H01L 23/48

(52) U.S. Cl. 257/751; 438/653; 257/E23.01; 257/E21.584

(57) ABSTRACT

A copper layer is formed without copper hillocks. Embodiments includes providing a copper layer above a substrate, planarizing the copper layer, performing hydrogen (H₂) plasma treatment on the copper layer in a first chamber, and forming a barrier layer over the copper layer in a second chamber, different from the first chamber.

### TECHNICAL FIELD

The present disclosure relates to forming copper layers in semiconductor devices. The present disclosure is particularly applicable to forming hillock-free copper layers in semiconductor devices.

### BACKGROUND

Copper hillocks are usually generated during copper dual damascene processes. Copper hillocks may cause inter layer shorts (ILSs) within semiconductor devices, may introduce nuisance counts, and may cause ineffective monitoring of yield defect densities. Based on these issues, there is a need to remove copper hillocks from copper layers.

Various methods have been developed in an attempt to remove copper hillocks from copper layers. In one method, after chemical mechanical polishing (CMP) to expose a copper layer, the copper layer may be annealed to stimulate the formation of copper hillocks. The copper hillocks may then be removed with an additional polishing step. Alternatively, the copper layer may be annealed in a reducing gas to suppress the formation of copper hillocks.

Further, to promote the adhesion of a barrier layer above the copper layer, the copper layer may be treated with an ammonia (NH₃) plasma treatment. However, the NH₃ plasma treatment may not be able to efficiently prevent the formation of copper hillocks and may also cause carbon (C) depletion from interlayer dielectric layers (ILDs). Hydrogen (H₂) plasma treatment has been used to remove a copper oxide (CuO) film that may form on the copper layer and promote copper hillock formation. However the H₂ from the H₂ plasma treatment has negative effects on the resistance and leakage of the copper layer through secondary reactions that occur in the process chamber, such as silicon (Si) reacting with hydrogen forming silane that then reacts with copper to form copper silicide (CuSiₓ) on the copper layer, which increases the resistance and leakage of the copper layer.

A need therefore exists for methodology enabling formation of hillock-free copper layers without increasing the resistance or leakage of the copper layer, and the resulting product.

### SUMMARY

An aspect of the present disclosure is an efficient method for fabricating copper layers without copper hillocks.

Another aspect of the present disclosure is a copper layer on a substrate without copper hillocks.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: providing a copper layer above a substrate, planarizing the copper layer, performing H₂ plasma treatment on the copper layer in a first chamber, and forming a barrier layer over the copper layer in a second chamber, different from the first chamber.

An aspect of the present disclosure includes performing the H₂ plasma treatment at 200 to 400° C. Another aspect includes performing the H₂ plasma treatment for 5 to 60 seconds. An additional aspect includes performing the H₂ plasma treatment at 200 to 600 watts (W). A further aspect includes planarizing the copper layer by CMP. An aspect also includes planarizing the copper layer in a different chamber than the first chamber. Another aspect includes the different chamber being the second chamber. A further aspect includes forming an ILD over the barrier layer. Another aspect includes annealing the copper layer prior to planarizing. Yet an additional aspect includes forming the barrier layer of a nitride, a silicon carbon nitride (SiCNH), or a combination thereof.

Another aspect of the present disclosure is a device including: a substrate, a H₂ plasma treated copper layer above the substrate, and a barrier layer over the copper layer, deposited in a different chamber than the H₂ plasma treatment, wherein the copper layer is free of copper hillocks.

Aspects include the copper layer including enlarged copper grain boundaries as compared to non-H₂ plasma treated copper layers. Another aspect includes the barrier layer including a nitride barrier layer, a SiCNH barrier layer, or a combination thereof. An additional aspect includes an ILD over the barrier layer. A further aspect includes the copper layer being H₂ plasma treated at 200 to 400° C. Another aspect includes the copper layer being H₂ plasma treated at 200 to 600 W for 5 to 60 seconds.

Another aspect of the present disclosure includes: providing a copper layer above a substrate, annealing the copper layer in a first chamber, CMP the copper layer in the first chamber, performing H₂ plasma treatment on the copper layer at 200 to 400° C. and 200 to 600 watts in a second chamber, different from the first chamber, and forming a barrier layer over the copper layer in the first chamber.

An additional aspect includes performing the H₂ plasma treatment for 5 to 60 seconds. A further aspect includes forming the barrier layer by depositing a nitride, SiCNH, or a combination thereof. Another aspect includes forming an ILD over the barrier layer.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawings and in which like reference numerals refer to similar elements and in which:

FIGS. 1 through 6 schematically illustrate a process flow for forming a copper layer without copper hillocks, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of copper hillocks attendant upon forming copper layers. In accordance with embodiments of the present disclosure, the copper layer is treated in a dedicated chamber with an H₂ plasma treatment to reduce the formation of copper hillocks.

Methodology in accordance with embodiments of the present disclosure includes providing a copper layer above a substrate, planarizing the copper layer, performing H₂ plasma treatment on the copper layer in a first chamber, forming a barrier layer over the copper layer in a second chamber, different from the first chamber, and forming an ILD over the barrier layer.

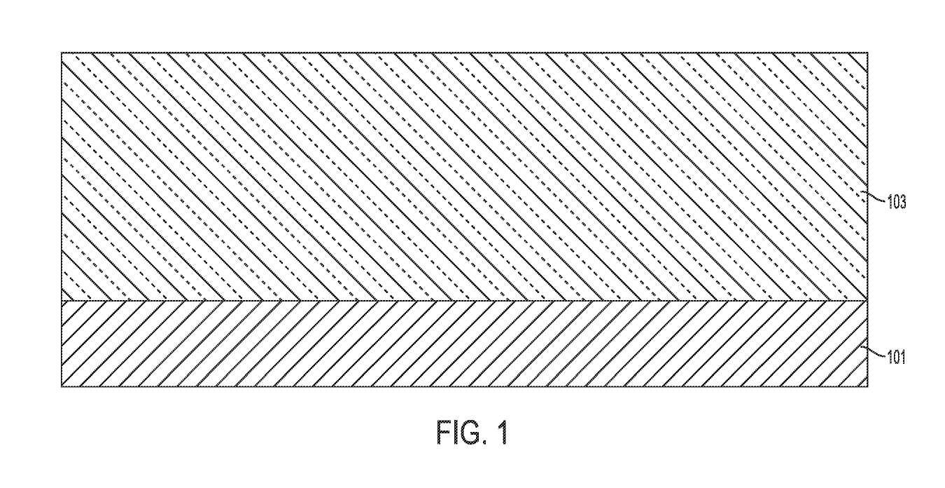

Adverting to FIG. 1, a method of forming a copper layer without copper hillocks, in accordance with an exemplary embodiment, begins with a substrate 101. The substrate 101 may be formed, for example, of Si. Above the substrate 101 may be formed one or more layers 103. The layers 103 may include the various layers of a transistor and/or any other layers that may be in a semiconductor device, such as an ILD. The layers 103 may be formed over the substrate 101 in a first process chamber (not shown for illustrative convenience) for manufacturing semiconductor devices. The first process chamber may be any process chamber that is conventionally used for forming the layers 103.

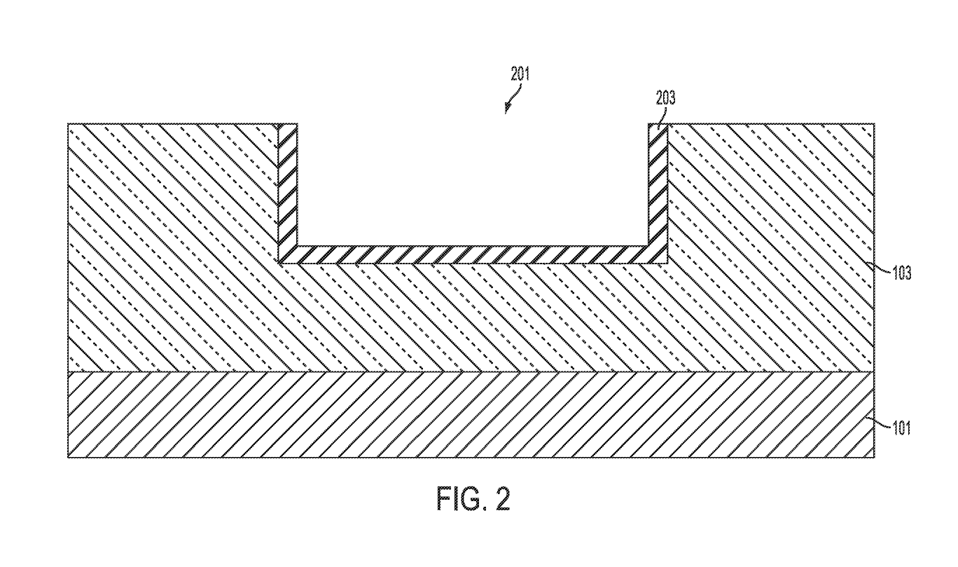

Adverting to FIG. 2, a recess 201 may be formed in the layers 103. Next, a barrier layer 203 may be conformally formed within the recess 201. The barrier layer 203 may be formed of a nitride (e.g., tantalum nitride (TaN)), SiCNH (e.g., NBlok), or a combination thereof.

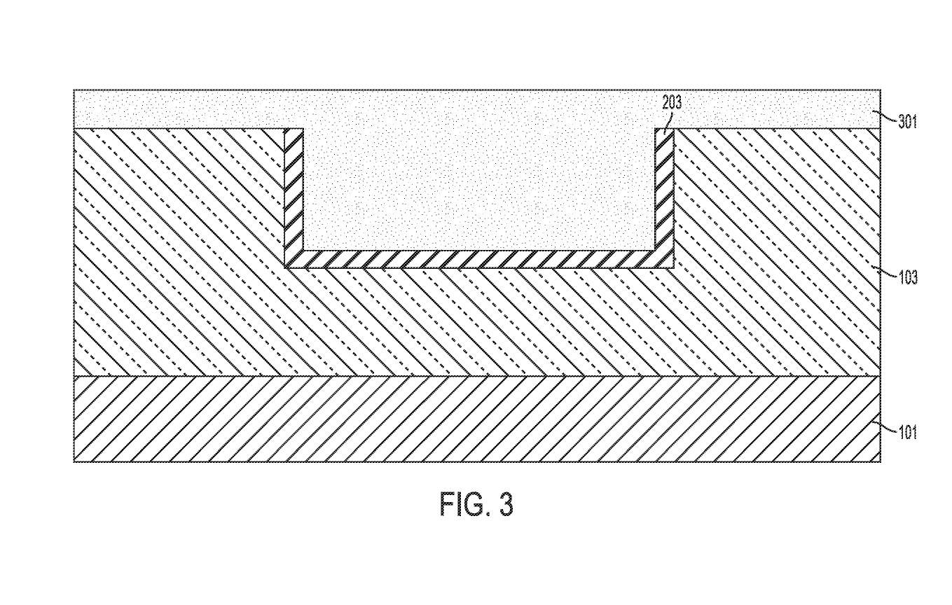

As illustrated in FIG. 3, a copper layer 301 may subsequently be formed over the layers 103 and filling the recess 201 over the barrier layer 203. The copper layer 301 may be formed according to any known process. Further, after the copper layer 301 is deposited, the copper layer 301 may be annealed according to any known annealing process. The copper layer 301 may be formed in any process chamber that is conventionally used for forming a copper layer. For purposes of explanation, the copper layer 301 may be formed in the first process chamber.

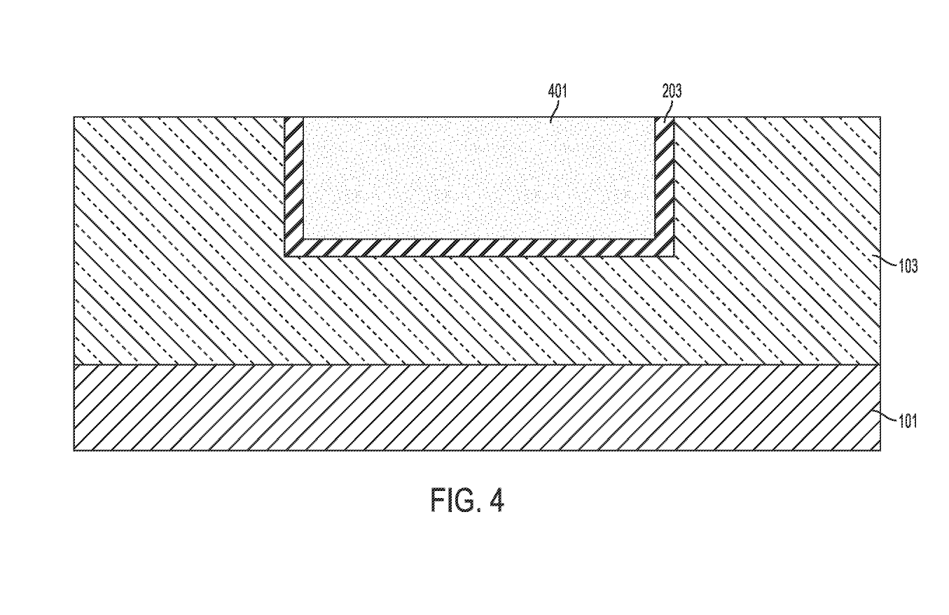

Next, the copper layer 301 may be planarized to be co-planar with the top surface of the layers 103, as illustrated in FIG. 4, to form the copper layer 401. For example, the copper layer 401 may be a through silicon via (TSV). Alternatively, annealing the copper layer 301 prior to planarizing the copper layer 301 may be omitted. In this instance, the copper layer 401 may be annealed after planarizing the copper layer 301. The planarization may be performed in any process chamber that is conventionally used for planarizing a copper layer. For purposes of explanation, the planarizing also may be performed in the first chamber.

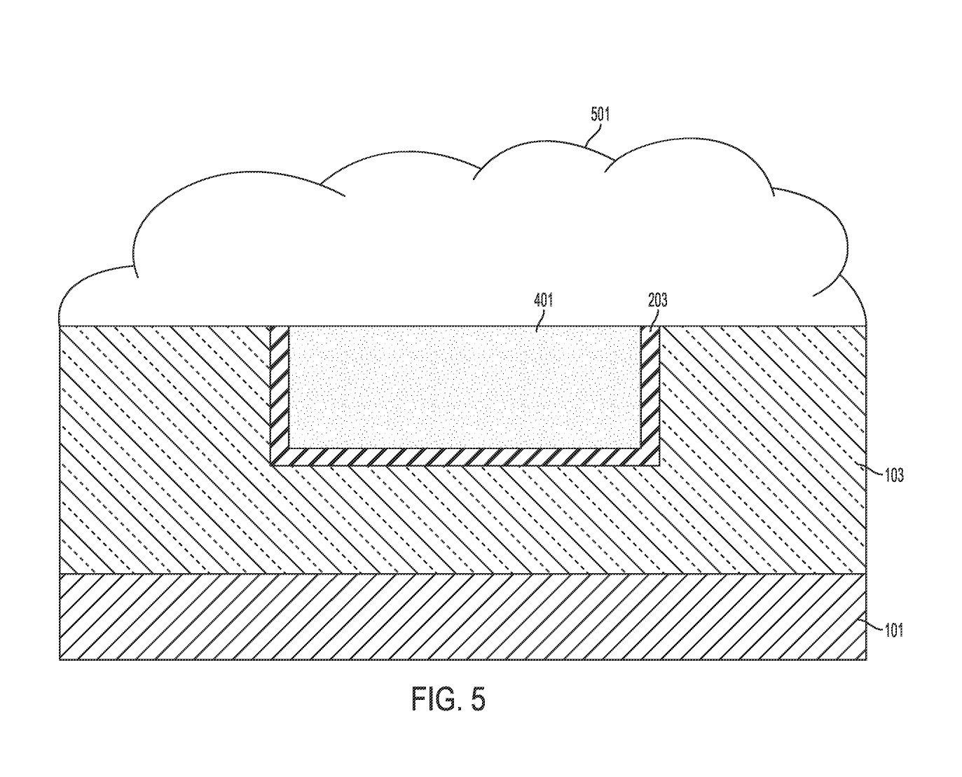

As illustrated in FIG. 5, the copper layer 401 may then be treated with a H₂ plasma treatment 501. The H₂ plasma treatment 501 may be at a temperature of 200 to 400° C. and at a power of 200 to 600 watts (W) and may last for 5 to 60 seconds (s). Additionally, the H₂ plasma treatment 501 is conducted in a different process chamber than the first chamber (or different than any process chamber previously used), such as a dedicated process chamber (e.g., a second process chamber). By performing the H₂ plasma treatment 501 in the second process chamber that is different than the first process chamber, the walls of the second process chamber for the H₂ plasma treatment are free from a silicon film (e.g., SiN) that would normally react with hydrogen to form silane, which would then react with the copper to form CuSiₓ, which increases the resistance and leakage of the copper layer 401. The H₂ plasma treatment 501 may be performed as the only step in the dedicated chamber (e.g., the second process chamber), as described. Alternatively, the H₂ plasma treatment 501 may be performed in an alternate chamber (e.g., the second process chamber) that may be used for other steps, such as any process chamber used for the previous steps described in FIGS. 1-4, as long as the other steps have no potential for depositing Si on the chamber walls. As a result, the dedicated chamber does not require periodic cleaning that otherwise is needed for process chambers to reduce the presence of free particles in the chamber.

The H₂ plasma treatment 501 enlarges grooves of the grain boundaries of the copper layer 401, which then act as buffer zones to suppress copper hillock formation. Use of the H₂ plasma treatment 501 also provides high efficiency for copper oxide (CuO) reduction to suppress the formation of copper hillocks and also provide adhesion between the copper layer 401 and subsequent layers above the copper layer 401.

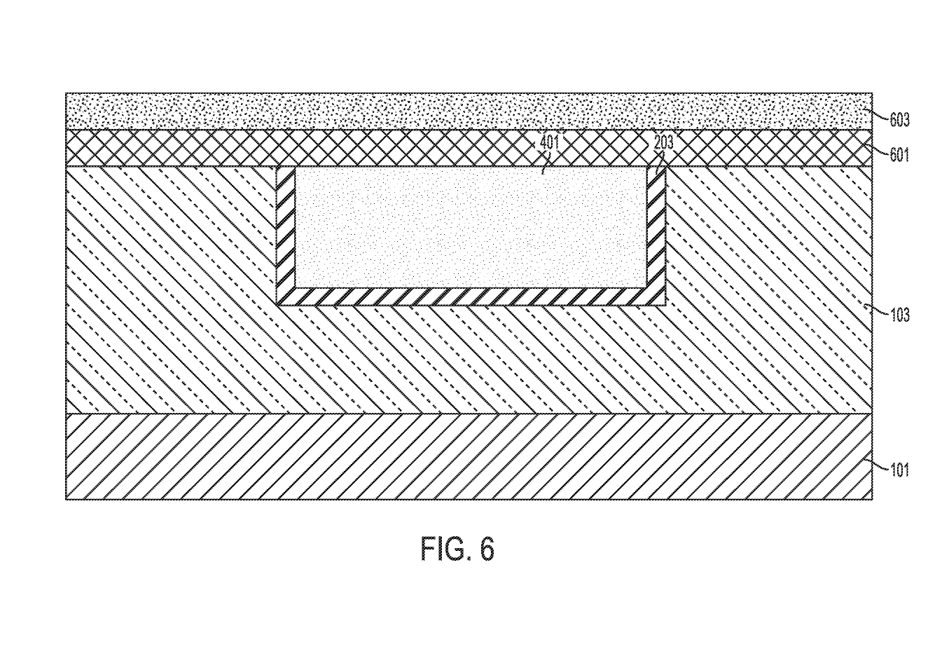

Adverting to FIG. 6, a barrier layer 601 subsequently may be formed over the copper layer 401, after the H₂ plasma treatment. The barrier layer 601 may be formed of a nitride, SiCNH (e.g., NBlok), or a combination thereof. The formation of the barrier layer 601 is performed in a separate chamber from the H₂ plasma treatment 501 (e.g., not performed in the second chamber) to prevent material of the barrier layer 601 from possibly depositing on the walls and affecting the subsequent H₂ plasma treatment of additional substrates. Thus, forming the barrier layer 601 may be performed in a dedicated process chamber (e.g., a third process chamber), or in any process chamber that is used with respect to the steps discussed in FIGS. 1-4 (e.g., the first process chamber). As discussed above, the H₂ plasma treatment improves the adhesion between the copper layer 401 and the barrier layer 601. Further, additional processing may occur after forming the barrier layer 601, such as forming a low-k ILD 603 over the barrier layer 601.

The embodiments of the present disclosure achieve several technical effects, including copper layers without copper hillocks and without increased resistance or leakage. Embodiments of the present disclosure enjoy utility in various industrial applications as, for example, microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of highly integrated semiconductor devices.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

1. A method comprising:
providing a copper layer above a substrate;
planarizing the copper layer;
performing hydrogen (H₂) plasma treatment on the copper layer in a first chamber; and
forming a barrier layer over the copper layer in a second chamber,
wherein the first chamber is dedicated for only H₂ plasma treatment of the copper layer.

2. The method according to claim 1, comprising performing the H₂ plasma treatment at 200 to 400° C.

3. The method according to claim 1, comprising performing the H₂ plasma treatment for 5 to 60 seconds.

4. The method according to claim 1, comprising performing the H₂ plasma treatment at 200 to 600 watts.

5. The method according to claim 1, comprising planarizing the copper layer by chemical mechanical polishing (CMP).

6. The method according to claim 1, comprising planarizing the copper layer in a different chamber than the first chamber the second chamber.

7. (canceled)

8. The method according to claim 1, further comprising forming an interlayer dielectric (ILD) over the barrier layer.

9. The method according to claim 1, further comprising annealing the copper layer prior to planarizing.

10. A method according to claim 1, comprising forming the barrier layer of a nitride, a silicon carbon nitride (SiCNH), or a combination thereof.

11. A device comprising:
a substrate;
a hydrogen (H₂) plasma treated copper layer above the substrate; and
a barrier layer over the copper layer, deposited in a different chamber from the H₂ plasma treatment,
wherein the copper layer is free of copper hillocks.

12. A device according to claim 11, wherein the copper layer includes enlarged copper grain boundaries as compared to non-H₂ plasma treated copper layers.

13. The device according to claim 11, wherein the barrier layer comprises a nitride barrier layer, a silicon carbon nitride (SiCNH) barrier layer, or a combination thereof.

14. A device according to claim 11, further comprising an interlayer dielectric (ILD) over the barrier layer.

15. A device according to claim 11, wherein the copper layer is hydrogen (H₂) plasma treated at 200 to 400° C.

16. A device according to claim 11, wherein the copper layer is hydrogen (H₂) plasma treated at 200 to 600 watts (W) for 5 to 60 seconds.

17. A method comprising:
providing a copper layer above a substrate;
annealing the copper layer in a first chamber;
chemical mechanical polishing (CMP) the copper layer in the first chamber;
performing hydrogen (H₂) plasma treatment on the copper layer at 200 to 400° C. and 200 to 600 watts in a second chamber; and
forming a barrier layer over the copper layer in the first chamber,
wherein the second chamber is dedicated for only H₂ plasma treatment of the copper layer.

18. The method according to claim 17, comprising performing the H₂ plasma treatment for 5 to 60 seconds.

19. The method according to claim 18, comprising forming the barrier layer by depositing a nitride, a silicon carbon nitride (SiCNH), or a combination thereof.

20. The method according to claim 18, further comprising forming an interlayer dielectric (ILD) over the barrier layer.
